(19) United States
(12) Patent Application Publication
(10) Pub. No.: US 2023/0093917 A1
(43) Pub. Date: Mar. 30, 2023

(54) Use Of Nuclear Magnetic Resonance For Gas Wettability And Supercritical Fluid Wettability Determination

(71) Applicant: Halliburton Energy Services, Inc., Houston, TX (US)

(72) Inventors: Songhua Chen, Katy, TX (US); Gabriela Singer, Richmond, TX (US)

(73) Assignee: Halliburton Energy Services, Inc., Houston, TX (US)

(21) Appl. No.: 17/531,665

(22) Filed: Nov. 19, 2021

Related U.S. Application Data
(60) Provisional application No. 63/250,332, filed on Sep. 30, 2021.

(51) Int. Cl. G01N 24/08; E21B 49/08

(52) U.S. Cl. CPC G01N 24/081; E21B 49/08

(57) ABSTRACT

An NMR based wettability index determination method for CO₂-liquid-solid system for CO2 and liquid phase wettability assessment may comprise acquiring ¹H NMR relaxation time measurements, analyzing brine signals for the comparable brine-filled pores from various step, applying a wettability index model constructed with NMR alone and calibrated with another wettability measurement, and applying the wettability index model to interpret wettability of CO2-containing rock system from corresponding NMR measurements.

### BACKGROUND

Rock samples or core samples taken from a formation may be analyzed to identify the properties and characteristic of one or more pores that may be attached to one another within the rock samples. Analyzing rock samples may be performed using NMR measurements. NMR measures an induced magnet moment of hydrogen nuclei (protons) contained within fluid-filled pore space of porous media such as reservoir rocks. Unlike conventional measurements (e.g., acoustic, density, neutron, and resistivity), which are dependent on mineralogy and respond to a rock matrix and fluid properties, NMR measurements respond to a presence of hydrogen in pore fluids, such as water and hydrocarbons, for example. NMR effectively responds to a volume, a composition, a viscosity, and a distribution of the pore fluids. NMR logs provide information about the quantities of fluids present, the properties of these fluids, sizes of the pores containing these fluids, and/or other rock characteristics.

Information from NMR logs may be utilized in CO₂ storage within a formation. One of rock characteristics affecting storage capacity and long-term security of CO₂ gas in underground formations such as depleted petroleum reservoirs, depleted underground aquifers, or deep ingenious rocks is the CO₂ wettability. On the other hand, H₂ storage capacity is affected by the H₂ wettability as well. Therefore, a method for measuring gas wettability is important for the selection of the CO₂ storage site and for the economic success of one form of important green energies, the hydrogen energy.

### BRIEF DESCRIPTION OF THE DRAWINGS

These drawings illustrate certain aspects of some examples of the present disclosure and should not be used to limit or define the disclosure.

FIG. 1 illustrates an example of a core drilling operation;

FIG. 2 illustrates a schematic view of an information handling system;

FIG. 3 illustrates is another schematic view of the information handling system;

FIG. 4A illustrates water-wet rock before CO₂ injection;

FIG. 4B illustrates water-wet rock after CO₂ injection;

FIG. 5A illustrates CO₂-wet rock before CO₂ injection;

FIG. 5B illustrates CO₂-wet rock after CO₂ injection;

FIG. 6 is a graph of cumulative T₂ distribution before and after CO₂ injection;

FIG. 7 illustrates an inversion workflow;

FIG. 8 illustrates a workflow for using 1H NMR relaxation time measurements to determine brine wettability in brine-CO₂ or scCO₂;

FIG. 9 is a graph for a phase diagram of CO₂;

FIG. 10 is a graph of contact angle and NMR wettability index calibration; and

FIG. 11 illustrates a workflow for determining a ¹³C NMR based wettability index.

### DETAILED DESCRIPTION

This disclosure details a method and system to a nuclear magnetic resonance (NMR) relaxation time measurement based method to fulfill both the gas wettability measurement need and the supercritical fluid wettability assessment needs. In examples, gas wettability measurements may be performed in a laboratory on core samples that have been removed from a formation. Discussed below are systems and methods for removing a core sample from a subterranean formation and analyzing the core sample to determine gas wettability measurements.

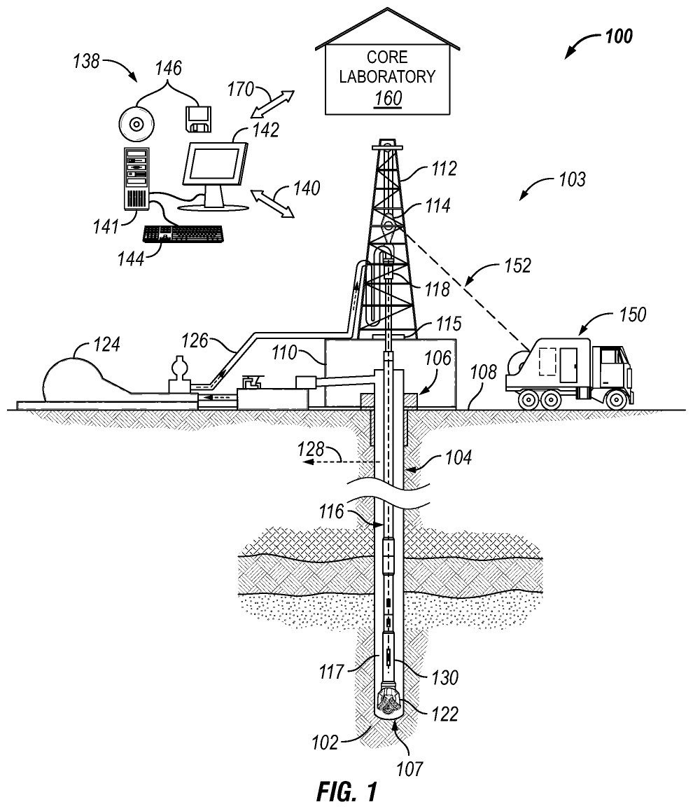

As illustrated in FIG. 1, the geological subsurface domain may comprise of multiple subterranean rock layers which, as a non-limiting example, may be classified and categorized by depositional age, depositional environment, or geologic properties to create one or more subterranean formations 100. In particular, one or more target subterranean formations may exist as a subset of the subterranean formations 100, wherein the target subterranean formations 102 may have an interstitial pore space that contains at least hydrocarbons. FIG. 1 further illustrates an example embodiment of a wellbore drilling system 103 which may be used to create a borehole 104 which fluidly couples target subterranean formation 102 to the surface 108. During downhole operations, wellbore drilling system 103 may perform operations for the cutting and collection of core samples wherein the execution of this operation may further comprise the cutting and collection of core samples. As illustrated, borehole 104 may extend from a wellhead 106 into a subterranean formation 102 from a surface 108. Generally, borehole 104 may comprise horizontal, vertical, slanted, curved, and other types of borehole geometries and orientations. Borehole 104 may be cased or uncased. In examples, borehole 104 may comprise a metallic member. By way of example, the metallic member may be a casing, liner, tubing, or other elongated steel tubular disposed in borehole 104.

Borehole 104 may extend through subterranean formations 100. As illustrated in FIG. 1, borehole 104 may extend generally vertically into subterranean formations 100, however borehole 104 may extend at an angle through subterranean formations 100, such as horizontal and slanted boreholes. For example, although FIG. 1 illustrates a vertical or low inclination angle well, high inclination angle or horizontal placement of the well and equipment may be possible. It should further be noted that while FIG. 1 generally depict land-based operations, those skilled in the art may recognize that the principles described herein are equally applicable to subsea operations that employ floating or sea-based platforms and rigs, without departing from the scope of the disclosure.

As illustrated, a drilling platform 110 may support a derrick 112 having a traveling block 114 for raising and lowering drill string 116. Drill string 116 may comprise, but is not limited to, drill pipe and coiled tubing, as generally known to those skilled in the art. A kelly 118 may support drill string 116 as it may be lowered through a rotary table 120. A drill bit 122 may be attached to the distal end of drill string 116 and may be driven either by a downhole motor and/or via rotation of drill string 116 from surface 108. Without limitation, drill bit 122 may comprise, roller cone bits, PDC bits, natural diamond bits, any hole openers, reamers, coring bits, and the like. As drill bit 122 rotates, it may create and extend borehole 104 that penetrates various subterranean formations 100. Proximally disposed to the drill bit may be a bottom hole assembly (BHA) 117 which without limitation may comprise stabilizers, reamers, mud motors, logging while drilling (LWD) tools, measurement while drilling (MWD) or directional drilling tools, heavy-weight drill pipe, drilling collars, jars, coring tools, and underreaming tools. A pump 124 may circulate drilling fluid through a feed pipe 126 through kelly 118, downhole through interior of drill string 116, through orifices in drill bit 122, back to surface 108 via annulus 128 surrounding drill string 116, and into a retention pit (not shown).

With continued reference to FIG. 1, drill string 116 may begin at wellhead 106 and may traverse borehole 104. Drill bit 122 may be attached to a distal end of drill string 116 and may be driven, for example, either by a downhole motor and/or via rotation of drill string 116 from surface 108. Drill bit 122 and drill string 116 may be progressed through one or more subterranean formations 100 until target subterranean formation 102 is reached.

Drill string 116, drill bit 122, and drilling BHA 117 may be removed from the well, through a process called “tripping out of hole,” or a similar process. A coring bit 122 and coring BHA 117 are installed on drill string 116 which is then run back into borehole 104 through a process which may be called “tripping in hole,” or a similar process. The face of coring bit 122 may comprise of a toroidal cutting edge with a hollow center that extends full-bore through the body of coring bit 122. With coring bit 122 being the endmost piece of equipment in BHA 117, disposed proximally thereto is a rock sample containment vessel which may be known as a core barrel 130. Once coring bit 122 is in contact with the bottom of the borehole 107 it is rotationally engaged with target subterranean formation 102 to cut and disengage a portion of target subterranean formation 102 in the form of a core. As coring bit 122 progresses further into target subterranean formation 102, the portion of the rock that is disengaged from target subterranean formation 102 is progressively encased in a core barrel 130 until the entirety of the sample is disengaged from target subterranean formation 102 and encased within core barrel 130. In some embodiments the core sample is relayed from core barrel 130 to the rig floor 115 by removing drill string 116 from borehole 104. In non-limiting alternate embodiments, a wireline truck 150 and a wireline, electric line, braided cable, or slick line 152 may be used to relay core barrel 130 through the center of drill string 116 to rig floor 115.

As illustrated, communication link 140 (which may be wired or wireless, for example) may be provided that may transmit data during the coring operation from BHA 117 to an information handling system 138 at surface 108. Information handling system 138 may comprise a personal computer 141, a video display 142, a keyboard 144 (i.e., other input devices.), and/or non-transitory computer-readable media 146 (e.g., optical disks, magnetic disks) that may store code representative of the methods described herein. In addition to, or in place of processing at surface 108, processing may also occur downhole as information handling system 138 may be disposed on BHA 117. As discussed above, the software, algorithms, and modeling are performed by information handling system 138. Information handling system 138 may perform steps, run software, perform calculations, and/or the like automatically, through automation (such as through artificial intelligence (“AI”), dynamically, in real-time, and/or substantially in real-time.

Once retrieved from borehole 104, the at least one core may be packaged and transported to a core laboratory 160 where a multitude of tests may be performed to identify create a core sample data set which may be populated with geological and petrophysical features wherein some non-limiting examples comprise formation sedimentology, mineralogy, formation wettability, fluid saturations and distributions, formation factor, pore structure and pore volume, capillary pressure behavior, sediment grain density, horizontal and vertical permeability and relative permeabilities, porosity, and presence of diagenesis. Communication link 170 may be configured to transmit data during core analysis operations in core laboratory 160 to an information handling system 138. The data obtained during the petrophysical analysis in core laboratory 160 may be stored in a structured database or in an unstructured form on an information handling system 138 which may comprise a personal computer 141, a video display 142, a keyboard 144 (i.e., other input devices.), and/or non-transitory computer-readable media 146 (e.g., optical disks, magnetic disks) that may store code representative of the methods described herein. In addition to, or in place of processing at core laboratory 160, processing related to the collection of the core data set may also take place offsite from core laboratory 160. As discussed above, the software, algorithms, and modeling are performed by information handling system 138. Information handling system 138 may perform steps, run software, perform calculations, and/or the like automatically, through automation (such as through artificial intelligence (“AI”), dynamically, in real-time, and/or substantially in real-time.

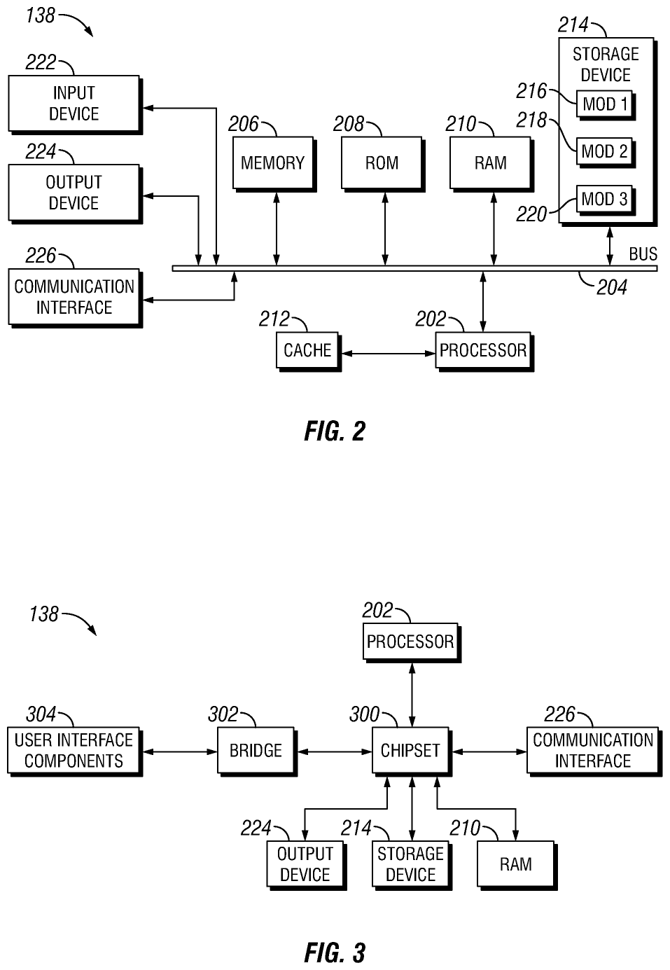

FIG. 2 illustrates an example information handling system 138 which may be employed to perform various steps, methods, and techniques disclosed herein. Persons of ordinary skill in the art will readily appreciate that other system examples are possible. As illustrated, information handling system 138 comprises a processing unit (CPU or processor) 202 and a system bus 204 that couples various system components including system memory 206 such as read only memory (ROM) 208 and random-access memory (RAM) 210 to processor 202. Processors disclosed herein may all be forms of this processor 202. Information handling system 138 may comprise a cache 212 of high-speed memory connected directly with, in close proximity to, or integrated as part of processor 202. Information handling system 138 copies data from memory 206 and/or storage device 214 to cache 212 for quick access by processor 202. In this way, cache 212 provides a performance boost that avoids processor 202 delays while waiting for data. These and other modules may control or be configured to control processor 202 to perform various operations or actions. Other system memory 206 may be available for use as well. Memory 206 may comprise multiple different types of memory with different performance characteristics. It may be appreciated that the disclosure may operate on information handling system 138 with more than one processor 202 or on a group or cluster of computing devices networked together to provide greater processing capability. Processor 202 may comprise any general-purpose processor and a hardware module or software module, such as first module 216, second module 218, and third module 220 stored in storage device 214, configured to control processor 202 as well as a special-purpose processor where software instructions are incorporated into processor 202. Processor 202 may be a self-contained computing system, containing multiple cores or processors, a bus, memory controller, cache, etc. A multi-core processor may be symmetric or asymmetric. Processor 202 may comprise multiple processors, such as a system having multiple, physically separate processors in different sockets, or a system having multiple processor cores on a single physical chip. Similarly, processor 202 may comprise multiple distributed processors located in multiple separate computing devices but working together such as via a communications network. Multiple processors or processor cores may share resources such as memory 206 or cache 212 or may operate using independent resources. Processor 202 may comprise one or more state machines, an application specific integrated circuit (ASIC), or a programmable gate array (PGA) including a field PGA (FPGA).

Each individual component discussed above may be coupled to system bus 204, which may connect each and every individual component to each other. System bus 204 may be any of several types of bus structures including a memory bus or memory controller, a peripheral bus, and a local bus using any of a variety of bus architectures. A basic input/output (BIOS) stored in ROM 208 or the like, may provide the basic routine that helps to transfer information between elements within information handling system 138, such as during start-up. Information handling system 138 further comprises storage devices 214 or computer-readable storage media such as a hard disk drive, a magnetic disk drive, an optical disk drive, tape drive, solid-state drive, RAM drive, removable storage devices, a redundant array of inexpensive disks (RAID), hybrid storage device, or the like. Storage device 214 may comprise software modules 216, 218, and 220 for controlling processor 202. Information handling system 138 may comprise other hardware or software modules. Storage device 214 is connected to the system bus 204 by a drive interface. The drives and the associated computer-readable storage devices provide nonvolatile storage of computer-readable instructions, data structures, program modules and other data for information handling system 138. In one aspect, a hardware module that performs a particular function comprises the software component stored in a tangible computer-readable storage device in connection with the necessary hardware components, such as processor 202, system bus 204, and so forth, to carry out a particular function. In another aspect, the system may use a processor and computer-readable storage device to store instructions which, when executed by the processor, cause the processor to perform operations, a method or other specific actions. The basic components and appropriate variations may be modified depending on the type of device, such as whether information handling system 138 is a small, handheld computing device, a desktop computer, or a computer server. When processor 202 executes instructions to perform “operations”, processor 202 may perform the operations directly and/or facilitate, direct, or cooperate with another device or component to perform the operations.

As illustrated, information handling system 138 employs storage device 214, which may be a hard disk or other types of computer-readable storage devices which may store data that are accessible by a computer, such as magnetic cassettes, flash memory cards, digital versatile disks (DVDs), cartridges, random access memories (RAMs) 210, read only memory (ROM) 208, a cable containing a bit stream and the like, may also be used in the exemplary operating environment. Tangible computer-readable storage media, computer-readable storage devices, or computer-readable memory devices, expressly exclude media such as transitory waves, energy, carrier signals, electromagnetic waves, and signals per se.

To enable user interaction with information handling system 138, an input device 222 represents any number of input mechanisms, such as a microphone for speech, a touch-sensitive screen for gesture or graphical input, keyboard, mouse, motion input, speech and so forth. Additionally, input device 222 may receive core samples or data derived from core samples obtained in core laboratory 160, discussed above. An output device 224 may also be one or more of a number of output mechanisms known to those of skill in the art. In some instances, multimodal systems enable a user to provide multiple types of input to communicate with information handling system 138. Communications interface 226 generally governs and manages the user input and system output. There is no restriction on operating on any particular hardware arrangement and therefore the basic hardware depicted may easily be substituted for improved hardware or firmware arrangements as they are developed.

As illustrated, each individual component describe above is depicted and disclosed as individual functional blocks. The functions these blocks represent may be provided through the use of either shared or dedicated hardware, including, but not limited to, hardware capable of executing software and hardware, such as a processor 202, that is purpose-built to operate as an equivalent to software executing on a general purpose processor. For example, the functions of one or more processors presented in FIG. 2 may be provided by a single shared processor or multiple processors. (Use of the term “processor” should not be construed to refer exclusively to hardware capable of executing software.) Illustrative embodiments may comprise microprocessor and/or digital signal processor (DSP) hardware, read-only memory (ROM) 208 for storing software performing the operations described below, and random-access memory (RAM) 210 for storing results. Very large-scale integration (VLSI) hardware embodiments, as well as custom VLSI circuitry in combination with a general-purpose DSP circuit, may also be provided.

FIG. 3 illustrates an example information handling system 138 having a chipset architecture that may be used in executing the described method and generating and displaying a graphical user interface (GUI). Information handling system 138 is an example of computer hardware, software, and firmware that may be used to implement the disclosed technology. Information handling system 138 may comprise a processor 202, representative of any number of physically and/or logically distinct resources capable of executing software, firmware, and hardware configured to perform identified computations. Processor 202 may communicate with a chipset 300 that may control input to and output from processor 202. In this example, chipset 300 outputs information to output device 224, such as a display, and may read and write information to storage device 214, which may comprise, for example, magnetic media, and solid-state media. Chipset 300 may also read data from and write data to RAM 210. A bridge 302 for interfacing with a variety of user interface components 304 may be provided for interfacing with chipset 300. Such user interface components 304 may comprise a keyboard, a microphone, touch detection and processing circuitry, a pointing device, such as a mouse, and so on. In general, inputs to information handling system 138 may come from any of a variety of sources, machine generated and/or human generated.

Chipset 300 may also interface with one or more communication interfaces 226 that may have different physical interfaces. Such communication interfaces may comprise interfaces for wired and wireless local area networks, for broadband wireless networks, as well as personal area networks. Some applications of the methods for generating, displaying, and using the GUI disclosed herein may comprise receiving ordered datasets over the physical interface or be generated by the machine itself by processor 202 analyzing data stored in storage device 214 or RAM 210. Further, information handling system 138 receive inputs from a user via user interface components 304 and execute appropriate functions, such as browsing functions by interpreting these inputs using processor 202.

In examples, information handling system 138 may also comprise tangible and/or non-transitory computer-readable storage devices for carrying or having computer-executable instructions or data structures stored thereon. Such tangible computer-readable storage devices may be any available device that may be accessed by a general purpose or special purpose computer, including the functional design of any special purpose processor as described above. By way of example, and not limitation, such tangible computer-readable devices may comprise RAM, ROM, EEPROM, CD-ROM or other optical disk storage, magnetic disk storage or other magnetic storage devices, or any other device which may be used to carry or store desired program code in the form of computer-executable instructions, data structures, or processor chip design. When information or instructions are provided via a network, or another communications connection (either hardwired, wireless, or combination thereof), to a computer, the computer properly views the connection as a computer-readable medium. Thus, any such connection is properly termed a computer-readable medium. Combinations of the above should also be comprised within the scope of the computer-readable storage devices.

Computer-executable instructions comprise, for example, instructions and data which cause a general-purpose computer, special purpose computer, or special purpose processing device to perform a certain function or group of functions. Computer-executable instructions also comprise program modules that are executed by computers in stand-alone or network environments. Generally, program modules comprise routines, programs, components, data structures, objects, and the functions inherent in the design of special-purpose processors, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

In additional examples, methods may be practiced in network computing environments with many types of computer system configurations, including personal computers, hand-held devices, multi-processor systems, microprocessor-based or programmable consumer electronics, network PCs, minicomputers, mainframe computers, and the like. Examples may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

As noted above, core samples removed from subterranean formation 102 to core laboratory 160 (e.g., referring to FIG. 1) for analyses. Lab analyses may be performed on an information handling system 138 (e.g., referring to FIG. 1) and may comprise measurement, storing data, reviewing data, altering data, analyzing data, and/or the like. In examples, measurements may be utilized to determine porosity within a formation sample as well as fluids that may be within the formation sample through relaxation times. Nuclear magnetic resonance (NMR) relaxation time (T₂) of fluids (i.e., liquid and gas) in porous solids (such as formation rock) may be determined by multiple factors including surface relaxivity p, surface roughness factor Rₛ, characteristic pore size r, and the bulk fluid relaxation time T_{2,b}, which may be expressed as:

$$\frac{1}{{T}_{2}} = \frac{ρ {R}_{s}}{r} + \frac{1}{{T}_{2 , b}} \qquad ( 1 )$$

where ρ is affected by the interfacial interactions of molecules between the mineral on the pore surface and the pore-filling fluid. In underground aquafer or petroleum reservoir rock formations, pore systems usually contain a distribution of pore sizes, therefore, the relaxation rate of each pore size, rₖ, may be expressed in

$${( \frac{1}{{T}_{2}} )}_{k} = \frac{{( ρ {R}_{s} )}_{k}}{{r}_{k}} + \frac{1}{{T}_{2 , b}} \qquad ( 2 )$$

For a rock with substantially uniform mineralogy, ρRₛ may be considered the same for all pores, thus Equation (2) becomes:

$${( \frac{1}{{T}_{2}} )}_{k} = \frac{ρ {R}_{s}}{{r}_{k}} + \frac{1}{{T}_{2 , b}} \qquad ( 3 )$$

During analyses of core sample, it is noted that water-wet and gas-wet pore systems have different surface relaxivity. Thus, if fluid in pore size rₖ initially was filled with brine (i.e., a likely scenario of an aquafer or depleted gas well before CO₂ storage), the surface relaxivity in the pore is determined by the interaction between the water and rock mineral on the pore surface. During recovery operations, CO₂ may be injected into the reservoir to aid in formation fluid recovery. Thus, after the CO₂ is injected into the formation, several expected outcomes may be possible.

For example, in on outcome CO₂ reacts with the minerals on the pore surface and forms a thin film partially on the pore wall, thus substantially changing the surface roughness and, in some cases, possibly the surface relaxivity, as well as wettability. However, the films are thin, thus the pore size rₖ and saturations are substantially unchanged resulting in the following relation:

$${( \frac{1}{{T}_{2 , before}} )}_{k} - {( \frac{1}{{T}_{2 , after}} )}_{k} = \frac{1}{{r}_{k}} [ {( ρ {R}_{s} )}_{before} - {{W}_{k} ( R {ρ}_{s} )}_{after} ] + [ \frac{1}{{T}_{2 , b}} - \frac{1}{{T}_{2 , {b}^{′}}} ] \qquad ( 4 )$$

where T_{2,b}, represent the relaxation time of the bulk fluid in the pore after CO₂ injection, and 0≤Wₖ≤1 is the fraction of the surface covered with water for pore k.

In another example, CO₂ may have a low solubility in brine, which is temperature and pressure dependent, this could result in a small difference in bulk fluid relaxation time change. For surface relaxation dominated system, the small difference in bulk relaxation time may be generally ignored in the calculation of the relaxation rate change before and after CO₂ injection. In which case, Equation (4) may be simplified to

$${( \frac{1}{{T}_{2 , before}} )}_{k} - {( \frac{1}{{T}_{2 after}} )}_{k} = \frac{1}{{r}_{k}} [ {( ρ {R}_{s} )}_{before} - {{W}_{k} ( ρ {R}_{s} )}_{after} ] \qquad ( 5 )$$

In another example, the chemical reaction between CO₂ and a formation sample is dynamic and involves dissolution and precipitation processes. The process may be time dependent during the initial injection of CO₂ to the formation, and it may also vary in long term as the storage media may change. In examples, the storage media change due to leakage, pressure change, and/or the like among other factors.

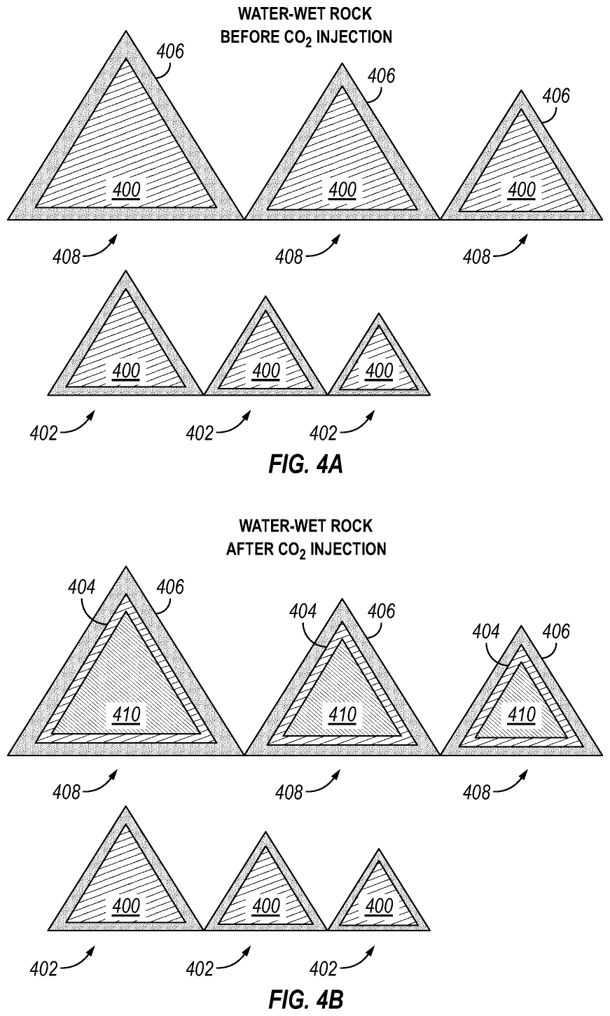

Another outcome that may be possible after CO₂ is injected into the formation, which is determined by injecting CO₂ into the formation sample, may be dependent on the initial and final wetting characteristics of the formation rock. In examples, the injected CO₂ has a preference of occupying different sized pores. As illustrated in FIGS. 4A and 4B, for a strongly water-wet rock, water 400 is the continuous phase, thus water 400 occupies smaller pores 402 and forms a film 404 on surface 406 of larger pores 408. FIG. 4B illustrates small pore 402 and large pores 408 in which CO₂ 410 has been injected. As illustrated in FIG. 4B, CO₂ 410 enters large pores 408 only.

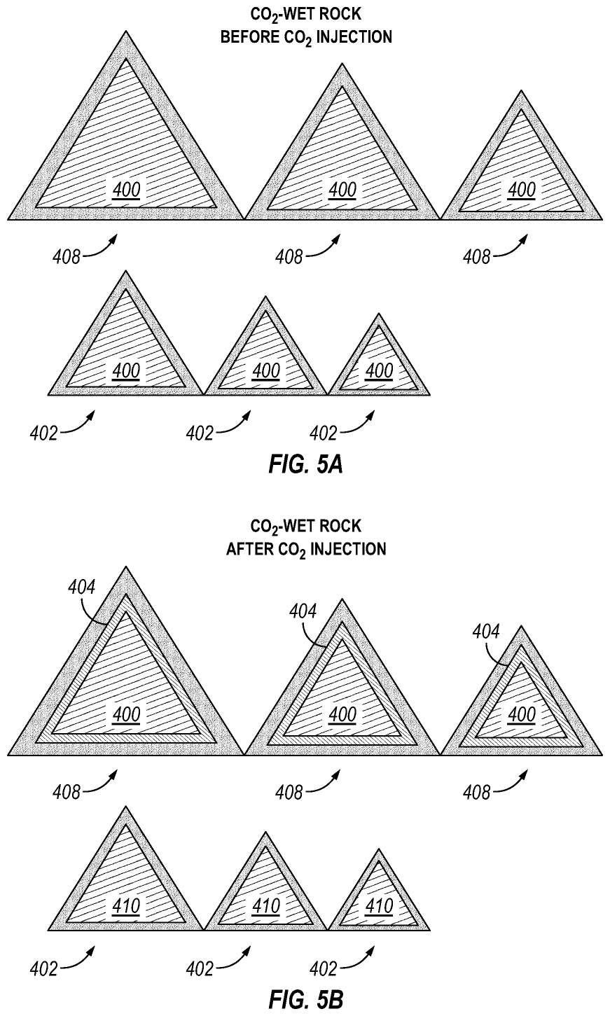

Referring to FIGS. 5A and 5B, for CO₂ wet rocks, CO₂ 410 is the continuous phase and occupies smaller pores 402 and forms film 404 on large pores 408, while water 400 is in middle of large pores 408. It should be noted that intermediate wet rock may fluctuate between the examples in FIGS. 4A-5B. Because CO₂ 410 does not contain hydrogen nuclei, for those pores 408, 402 that CO₂ 410 substantially replaces water 400, there is no hydrogen NMR signal. For pores 408, 402 that are substantially occupied by water 400, the ¹H (hydrogen nucleus) NMR signal amplitude is substantially unchanged, but the relaxation time of these pores 408, 402 depends on the surface interfacial property change caused by CO₂ 410 reaction with surface 406.

In another outcome that may be possible after CO₂ 410 is injected into the formation may be dependent on distribution of pore sizes. In examples, after CO₂ 410 injection, small pores 402 may be filled with CO₂ 410 and large pores 408 are filled with water 400 (e.g., referring to FIG. 5B), only large pores 408 may contribute to the NMR signal. Equation (5) represents collectively the pores occupied by water 400 after CO₂ 410 injection, or storage, becomes (assuming that there is no diffusive coupling)

$$Δ ( \frac{1}{{T}_{2 GM \_ w}} ) = \frac{1}{{r}_{GM \_ w}} [ {( ρ {R}_{s} )}_{before} - {{W}_{GM \_ w} ( ρ {R}_{s} )}_{after} ] \qquad ( 6 )$$

and for those pores 402, 408 occupied by CO₂ 410, after CO₂ injection, or storage, there is no ¹H NMR signal since these pores do not contain water.

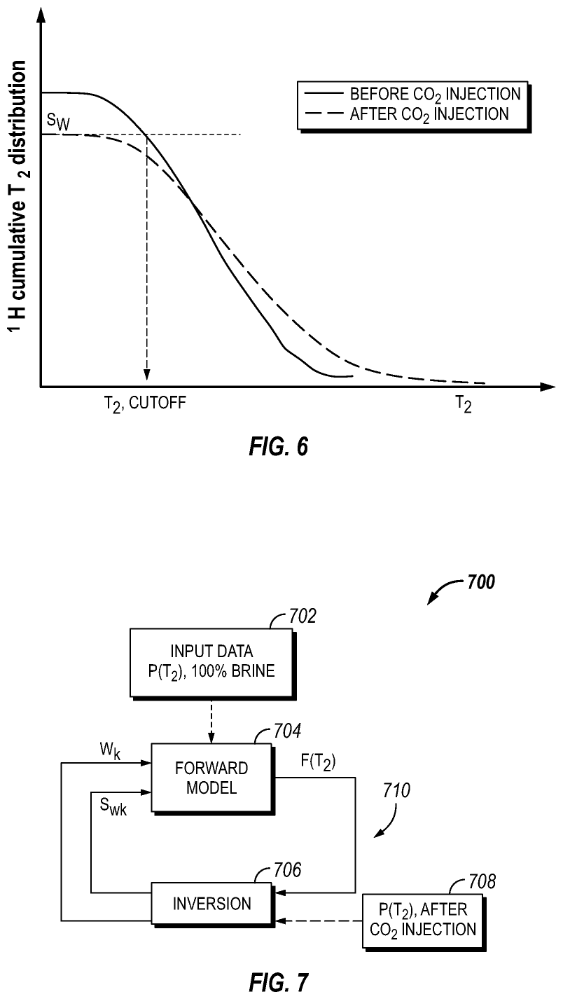

The subscript GM_w represents water-occupied pores after CO₂ injection in the formation. In the case of FIGS. 4A and 4B, GM_w is the log-mean of the entire T₂ distribution. In the case of FIGS. 5A and 5B, GM_w is the log-mean above a certain cutoff T_{2, cutoff} (i.e., the log-mean of large pores alone) as determined from FIG. 6, discussed below.

During measurement operations, the signal amplitude may be estimated from the ¹H NMR signal amplitude before and after CO₂ in the formation. Normalizing the NMR signal amplitude corresponding to original fully brine saturated rock to unity, the ¹H NMR signal amplitude after CO₂ in the formation equals water saturation, S_{w}.

Further, if the water filled and non-water filled pores are substantially separated in the T₂ distributions, if there is no diffusive coupling, a wettability index may be constructed based on Equation (6). However, if water-filled pores and CO₂ filled pores occupy different sized pores depending on the wettability, the

$$\frac{1}{{T}_{2 GM \_ w}}$$

in Equation (6) may be determined from the cumulative T₂ distribution by including signal up to Sw, as illustrated in FIG. 6.

In another example, for a general case, after CO₂ injection the water saturation varies from pore to pore, the pores wettability and saturation may both be unknown, and in this case Equation (3) becomes:

$${( \frac{1}{{T}_{2 , before}} )}_{k} - {( \frac{1}{{T}_{2 , after}} )}_{k} = \frac{1}{{r}_{k}} [ {( ρ {R}_{s} )}_{before} - \frac{{W}_{k}}{{S}_{w , k}} {( ρ {R}_{s} )}_{after} ] + [ \frac{1}{{T}_{2 , b}} - \frac{1}{{T}_{2 , {b}^{′}}} ] \qquad ( 7 )$$

where S_{w,k} is the water saturation of pore k. In this case both the saturation, S_{w,k}, and wettability, Wₖ, may be determined as a function of pore size from the inversion of NMR T₂ data after CO₂ injection. The inversion workflow 700 is illustrated in FIG. 7. Assuming that the CO₂ dissolved in water does not affect the bulk T₂, Equation (7) becomes

$${( \frac{1}{{T}_{2 , before}} )}_{k} - {( \frac{1}{{T}_{2 , after}} )}_{k} = \frac{1}{{r}_{k}} [ {( ρ {R}_{s} )}_{before} - \frac{{W}_{k}}{{S}_{w , k}} {( ρ {R}_{s} )}_{after} ] \qquad ( 8 )$$

Inversion workflow 700 may begin with block 702, in which initial input data is determined and then fed into a forward model of block 704. Inputs from block 702 that may be fed into the inversion comprise the T₂ distributions before and after injection. If the presence of CO₂ affects the T₂ bulk value for water, the bulk values for the water before CO₂ injection and after may be measured and used as inputs to the inversion. Given an initial guess for S_{w,k} and Wₖ, forward model of block 704 may output a fit to the T₂ distribution, F(T₂). The inversion in block 706 computes the x2 misfit between the measured T₂ distributions from block 708 and computed T₂ distributions and then updates the next guess for S_{w,k} and Wₖ. Loop 710 may continue until x² is sufficiently reduced.

The term Rₛ, before and after injection, is measured using Rₛ from LSCM and ρ is measured from BET, or from DT₂ of fully brine saturated rock. In the case when the surface relaxivity, ρ, before and after CO₂ injection, stays the same, Equations 4 through 8 may be simplified by taking ρ outside the parenthesis. For example, Equation 8 becomes

$${( \frac{1}{{T}_{2 , before}} )}_{k} - {( \frac{1}{{T}_{2 , after}} )}_{k} = \frac{ρ}{{r}_{k}} [ {( {R}_{s} )}_{before} - \frac{{W}_{k}}{{S}_{w , k}} {( {R}_{s} )}_{after} ] \qquad ( 9 )$$

The surface roughness may be measured with, such as but not limited to, Laser Confocal Scanning Microscopy (LCSM) measurement. However, such measurement may not be needed for wettability characterization. Both ρ and Rₛ may be affected by CO₂ caused chemical reaction during the injection period that lasts several days, weeks, or months, and the wettability of the rock is also changing. NMR based wettability index may be derived by calibrating the relaxation time shift for a given rock type and a given gas type using a known gas wettability measurement. Once calibration has been performed, an NMR relaxation rate difference may be used as a wettability index. A calibration that may be performed is using contact angle wettability measurement (which may be referred to simply as contact angle). NMR relaxation time base wettability index characterization has been reported for fluids containing liquid phases of water and hydrocarbon. One of the major requirements for using the ¹H NMR based wettability of oil-water-mineral system is the separation of the oil and water ¹H response on the relaxation time distribution. If the two fluid phases' NMR responses significant overlap, the accuracy of this method may be impacted.

The systems and methods described below may address issue of ambiguity of quantifying two liquid phases and the methods provide a solution of determining CO₂ wettability and brine phase wettability independently. The method involves using ¹H NMR relaxation time (T₁ or T₂ measurement) for determining brine wettability index, as discussed below.

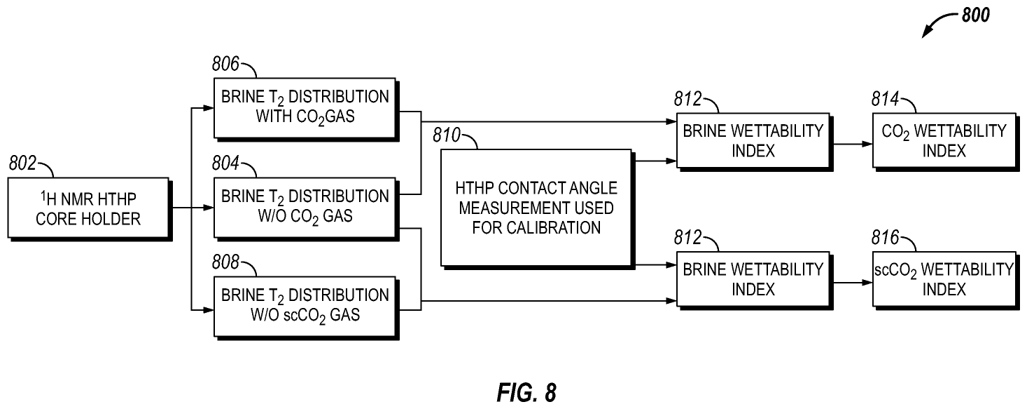

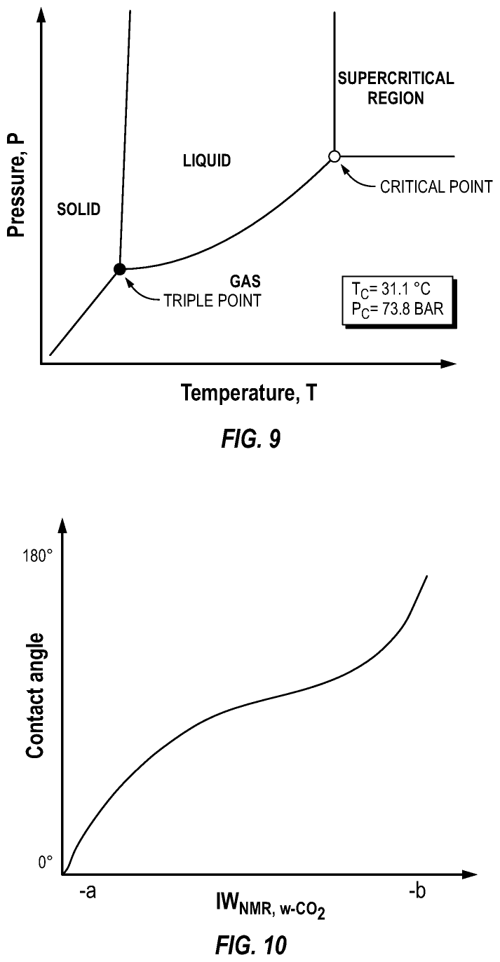

FIG. 8 illustrates workflow 800 in which CO₂ wettability and brine phase wettability may be determined independently. Workflow 800 may begin with block 802, in which a formation sample is placed inside a high-temperature, high-pressure NMR HTHP core holder. When dealing with supercritical CO₂, the temperature must be greater than 31.1° C. and the pressure must be higher than 73.8 bar in order to ensure the CO₂ reach the supercritical phase. For dealing with gas phase CO₂, the temperature and pressure state of the core holder should operate within the gas phase region illustrated in FIG. 9. Since CO₂ wettability is expected to vary with temperature and pressure, NMR relaxation time measurements may be conducted in a range of temperatures and pressures. For a typical depleted oil and gas well to use for CO₂ storage, the reservoir temperature and pressure may place CO₂ in a supercritical state. For shallow aquafers, the lower pressure and temperature may result in CO₂ in a gas state. During measurement operations, ¹H NMR T₂ experiments may be conducted in this type of experiment for brine wettability determination. Because CO₂ or scCO₂ contain no ¹H, therefore, the NMR signal response in such experiment is only the contribution from the brine phase fluid. Thus, there may be no need to determine and separate different fluid phases in NMR response.

The information from block 802 may be passed to block 804. In block 804, experimental procedures may comprise conducting the Carr-Purcell-Meiboom-Gill (CPMG) echo train acquisition corresponding to a fully brine saturated rock (brine-mineral system), which contains no CO₂ (i.e., CO₂ free). This measurement is a baseline and, in a water-wet rock, this ¹H NMR response is the water-wet response. Next, CO₂ gas is injected in the core holder at a temperature and pressure combination that corresponding to CO₂ gas phase state defined by FIG. 9 It should be noted that CO₂ gas may be referred to as CO₂ fluid and/or gas. Then, in block 806, another CPMG echo train with the same data acquisition parameters is acquired. 13 Optionally, the same CPMG echo train data acquisition experiment may be repeated with different pressure and temperature settings. The CPMG echo trains acquired in these experiments may be processed with a multiexponential inversion kernel matrix to obtain the brine T₂ distribution corresponding to their fluid state in the corresponding brine-mineral or brine-CO₂ gas-mineral system.

Additionally, in block 808, data acquisition and inversion processing may be conducted with a brine saturated core (brine-scCO₂-mineral), which contains no scCO₂ gas (i.e., scCO₂ free). The result is the brine T₂ distribution corresponding to their fluid state in the corresponding brine-scCO₂ gas-mineral system. The combination of the T₂ distribution information obtained from blocks 804 and 808, or from blocks 804 and 806 may determine Δ

$$( \frac{1}{{T}_{2}} )$$

using any of the equations in Equations 6 through 8 which corresponds to contact angle of 0°. In other examples, the relaxation time measurement of the brine in a completely non-water wet system is the bulk relaxation time

$$\frac{1}{{T}_{2 , o - wet}} = \frac{1}{{T}_{2 , b}}$$

because ρₒ≈0, which is determining by conducting the bulk brine T₂ measurement and it does not require actually treating rock to completely oil-wet for obtain this information. This corresponds to contact angle of 180°. Note these two baseline NMR responses do not involve CO₂ in the rock formation. All the intermediate-wet cases may have the relaxation time between these two values. In block 810, to map the relaxation rate of all intermediate contact angle for calibration purpose, multiple measurements at different NMR and independent contact angle measurements by either optical or force tensiometers may be conducted in the same rock to establish a correlation, which is used as a reference.

For calibration methods, there may be various options to establish the NMR based wettability index in brine-CO₂-rock system for blocks 812, and 814. One option is directly using the relaxation rate difference, from Equations (6), (7), or (8), with contact angle calibration. This calibration may depend on r_{GM_w}, which may utilize an additional, separate measurement. Another option may be to use a ratio approach described below. In Equation (6), the

$$\frac{{( ρ {R}_{s} )}_{b efore}}{{r}_{GM \_ w}}$$

may be determined from the baseline measurement:

$$\frac{1}{{T}_{2 G {M}_{w} , before}} = \frac{{( ρ {R}_{s} )}_{b efore}}{{r}_{GM \_ w}} \qquad ( 11 )$$

$$and$$

$$Δ ( \frac{1}{{T}_{2 S , GM \_ w}} ) = ( \frac{{W}_{GM \_ w}}{{S}_{w}} \frac{{( ρ {R}_{s} )}_{after}}{{( ρ {R}_{s} )}_{b efore}} - 1 ) {( \frac{1}{{T}_{2 S , GM}} )}_{before} \qquad ( 12 )$$

which is independent of pore size.

### Rearranging,

$${W}_{GM \_ w} = \frac{{( ρ {R}_{s} )}_{b efore}}{{( ρ {R}_{s} )}_{after}} {S}_{w} [ Δ ( \frac{1}{{T}_{2 S , GM}} ) / {( \frac{1}{{T}_{2 S , GM}} )}_{before} + 1 ] \qquad ( 13 )$$

The general expression for the wettability index is

IW_{NMR,w-CO}_{₂}=2W_{GM_w}−1 (14)

This allows for the NMR based brine-CO2-rock system wettability index, assuming

$$\frac{{( ρ {R}_{s} )}_{b efore}}{{( ρ {R}_{s} )}_{after}} {S}_{w} = 1 \qquad ( 15 )$$

to be defined by this ratio

$${IW}_{NMR , w - C {O}_{2}} = 1 ∓ 2 Δ ( \frac{1}{{T}_{2 GM \_ w}} ) / {( \frac{1}{{T}_{2 GM \_ w}} )}_{before} \qquad ( 16 )$$

Equation (16) implies that IW_{NMR,w-CO}_{₂} is determined only with NMR T₂ measurement and data analysis. Equation (16) indicates that the same wettability index may also be identified from independent surface relaxivity and surface roughness measurement. The wettability index IW_{NMR,w-CO}_{₂} is bound by −1≤IW_{NMR,w-CO}_{₂}≤1, where IW_{NMR,w-CO}_{₂}=1 implies a fully water-wet rock. Alternatively, the NMR wettability index may also be scaled and normalized to a more convenient range [−1 1], or [a b], where a and b are two numbers. A contact angle IW_{NMR,w-CO}_{₂} calibration is illustrated in FIG. 10.

Method discussed above may measure the wettability of brine phase and soCO2 wettability index. For brine-CO₂-rock mineral system, the CO₂ wettability is determined as the supplementary contact angle from the brine contact angle value. Thus, when NMR based wettability index is calibrated with contact angle measurement, the NMR based wettability index for brine may be converted to the contact angle for brine phase and subsequently the supplementary angle.

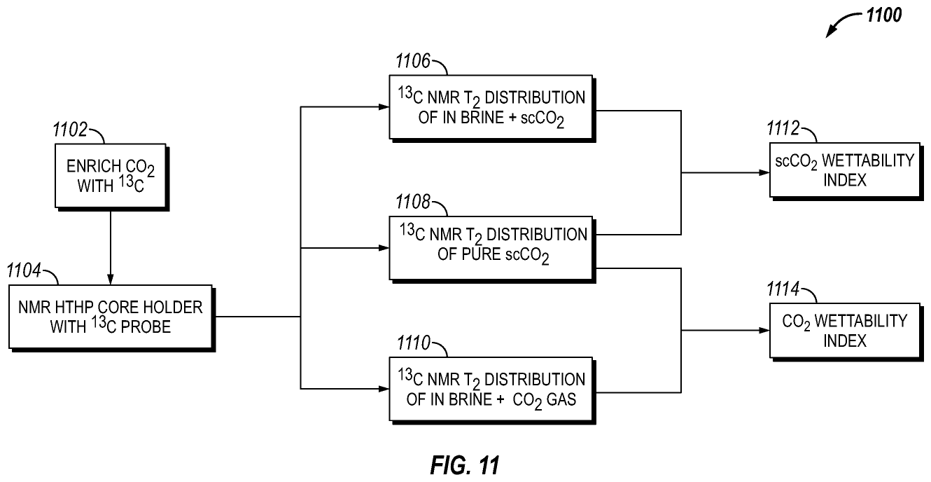

FIG. 11 illustrates workflow 1100, which may be utilized to for the direct determination of CO₂ wettability index using ¹³C NMR measurements. Because the natural abundance of ¹³C is only about 1.1%, the NMR signal strength is low. Thus, workflow 1100 may begin in block 1102 in which the first step for contacting ¹³C NMR is to enrich CO₂ with ¹³C in core laboratory 160 (e.g., referring to FIG. 1), on a formation sample core plugs. In block 1104, an NMR High Temperature High Pressure (HTHP) core holder with a ¹³C NMR probe may be utilized to conduct the ¹³C NMR experiment. Because the gyromagnetic ratio of ¹³C is only approximately one-quarter of that of ¹H, for the same static magnetic field, the resonance frequency is approximately one-quarter of that of ¹H. Thus, for the purpose of adequate SNR, a higher magnetic field NMR system may be used to conduct the ¹³C NMR than the typical ¹H NMR core analyzers use. In block 1108, the ¹³C NMR experiments may be conducted in pure gaseous phase CO₂, and/or supercritical phase CO₂ in a rock sample first, which serves as the baseline NMR response. The experiment type may be, but not limited to, a CPMG T₂ measurement. Subsequently, similar measurements may be conducted at the mixed brine-CO₂-mineral system in blocks 1106 and 1110. The shift of T2 distributions in block 1108 and 1110, in comparison to the baseline state found in block 1106, respectively, may be used to compute ¹³C NMR based CO₂ wettability index using Equation (16) directly for blocks 1112 and 1114.

Improvements over the current art are that there is no NMR based method for determining the CO2 gas and supercritical wettability. These methods and systems may be performed in a lab on formation samples, taken from a target subterranean formation. Accordingly, the systems and methods of the present disclosure allow for identifying CO2 gas and supercritical wettability, using NMR methods and systems. The systems and methods may comprise any of the various features disclosed herein, including one or more of the following statements.

Statement 1: A method may comprise acquiring two or more ¹H nuclear magnetic resonance (NMR) relaxation time measurements from a formation sample at different CO₂ containing states, analyzing two or more brine signals from the formation sample to identify one or more brine-filled pores in the formation sample, and applying a brine wettability index to the two or more brine signals.

Statement 2. The method of statement 1, further comprising injecting the formation sample with CO₂ gas.

Statement 3. The method of statement 2, further comprising taking a second set of brine signals from the formation sample with the CO₂ gas injected in the formation sample.

Statement 4. The method of statement 3, further comprising performing a multiexponential inversion kernel matrix with the two or more brine signals and the second set of brine signals to find a brine distribution.

Statement 5. The method of statement 4, further comprising cross-validating a contact angle wettability measurement with an NMR based wettability index.

Statement 6. The method of statement 5, further comprising forming the brine wettability index from the two or more ¹H NMR relaxation time measurements of the formation sample a different CO₂ containing states and the two or more brine signals.

Statement 7. The method of statement 6, further forming a CO₂ wettability index from the brine wettability index.

Statement 8. The method of any preceding statements 1 or 2, further comprising injecting the formation sample with a scCO₂ gas.

Statement 9. The method of statement 8, further comprising taking a second set of brine signals from the formation sample with the scCO₂ gas injected in the formation sample.

Statement 10. The method of statement 9, further comprising performing a multiexponential inversion kernel matrix with the two or more brine signals and the second set of brine signals to find a brine distribution.

Statement 11. The method of statement 10, further comprising cross-validating a contact angle wettability measurement with an NMR based wettability index.

Statement 12. The method of statement 11, further comprising forming the brine wettability index from one or more NMR measurements of the formation sample that is scCO₂ free, the formation sample with scCO₂, and the two or more brine signals.

Statement 13. The method of statement 12, further forming a scCO₂ wettability index from the brine wettability index.

Statement 14. The method of any preceding statements 1, 2, or 8, wherein one of the different CO₂ containing states is a CO₂ free state.

Statement 15. The method of any preceding statements 1, 2, 8, or 14, wherein one of the different CO₂ containing states are at a first time during a CO₂ injection into the formation sample and a second time during a storing of the formations sample this is injected with CO₂.

Statement 16. A method may comprise enriching CO₂ with ¹³C to form a CO₂ fluid, injecting the CO₂ fluid into a formation sample which may contain a liquid, conducting ¹³C NMR relaxation time (T₂) measurements for at least two states, finding a ¹³C NMR T₂ shift between the at least two states from the formation sample with the CO₂ fluid, and finding a wettability index from the ¹³C NMR T₂ shift between the ¹³C NMR relaxation time (T₂) measurements and for at least two different CO₂ containing states.

Statement 17. The method of statement 16, wherein one of the at least two different CO₂ containing states are at a first time during a CO₂ injection into the formation sample and a second time during a storing of the formations sample this is injected with CO₂

Statement 18. The method of any preceding statements 16 or 17, wherein the at least two different CO₂ containing states correspond to different CO₂ concentration is the formation sample.

Statement 19. The method of any preceding statements 16-18, further comprising injecting the formation sample with a brine solution.

Statement 20. The method of statement 19, further comprising finding the ¹³C NMR T₂ shift from the formation sample with the CO₂ fluid and the brine solution.

Statement 21. The method of statement 20, further comprising using the ¹³C NMR T₂ shift from the formation sample with the CO₂ fluid and the brine solution to find the wettability index.

Statement 22. The method of any preceding statements 16-18 or 19, further comprising injecting the formation sample with a brine solution and the CO₂ fluid, wherein the CO₂ fluid is scCO₂.

Statement 23. The method of statement 22, further comprising finding the ¹³C NMR T₂ shift from the formation sample with the CO₂ fluid and the brine solution.

Statement 24. The method of statement 23, further comprising using the ¹³C NMR T₂ shift from the formation sample with the CO₂ fluid and the brine solution to find the wettability index.

Although the present disclosure and its advantages have been described in detail, it should be understood that various changes, substitutions and alterations may be made herein without departing from the spirit and scope of the disclosure as defined by the appended claims. The preceding description provides various examples of the systems and methods of use disclosed herein which may contain different method steps and alternative combinations of components. It should be understood that, although individual examples may be discussed herein, the present disclosure covers all combinations of the disclosed examples, including, without limitation, the different component combinations, method step combinations, and properties of the system. It should be understood that the compositions and methods are described in terms of “comprising,” “containing,” or “including” various components or steps, the compositions and methods can also “consist essentially of” or “consist of” the various components and steps. Moreover, the indefinite articles “a” or “an,” as used in the claims, are defined herein to mean one or more than one of the element that it introduces.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, whenever a numerical range with a lower limit and an upper limit is disclosed, any number and any comprised range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values even if not explicitly recited. Thus, every point or individual value may serve as its own lower or upper limit combined with any other point or individual value or any other lower or upper limit, to recite a range not explicitly recited.

Therefore, the present examples are well adapted to attain the ends and advantages mentioned as well as those that are inherent therein. The particular examples disclosed above are illustrative only and may be modified and practiced in different but equivalent manners apparent to those skilled in the art having the benefit of the teachings herein. Although individual examples are discussed, the disclosure covers all combinations of all of the examples. Furthermore, no limitations are intended to the details of construction or design herein shown, other than as described in the claims below. Also, the terms in the claims have their plain, ordinary meaning unless otherwise explicitly and clearly defined by the patentee. It is therefore evident that the particular illustrative examples disclosed above may be altered or modified and all such variations are considered within the scope and spirit of those examples. If there is any conflict in the usages of a word or term in this specification and one or more patent(s) or other documents that may be incorporated herein by reference, the definitions that are consistent with this specification should be adopted.

What is claimed is:

1. A method comprising:
acquiring two or more ¹H nuclear magnetic resonance (NMR) relaxation time measurements from a formation sample at different CO₂ containing states;
analyzing two or more brine signals from the formation sample to identify one or more brine-filled pores in the formation sample; and
applying a brine wettability index to the two or more brine signals.

2. The method of claim 1, further comprising injecting the formation sample with CO₂ gas.

3. The method of claim 2, further comprising taking a second set of brine signals from the formation sample with the CO₂ gas injected in the formation sample.

4. The method of claim 3, further comprising performing a multiexponential inversion kernel matrix with the two or more brine signals and the second set of brine signals to find a brine distribution.

5. The method of claim 4, further comprising cross-validating a contact angle wettability measurement with an NMR based wettability index.

6. The method of claim 5, further comprising forming the brine wettability index from the two or more ¹H NMR relaxation time measurements of the formation sample a different CO₂ containing states and the two or more brine signals.

7. The method of claim 6, further forming a CO₂ wettability index from the brine wettability index.

8. The method of claim 1, further comprising injecting the formation sample with a scCO₂ gas.

9. The method of claim 8, further comprising taking a second set of brine signals from the formation sample with the scCO₂ gas injected in the formation sample.

10. The method of claim 9, further comprising performing a multiexponential inversion kernel matrix with the two or more brine signals and the second set of brine signals to find a brine distribution.

11. The method of claim 10, further comprising cross-validating a contact angle wettability measurement with an NMR based wettability index.

12. The method of claim 11, further comprising forming the brine wettability index from one or more NMR measurements of the formation sample that is scCO₂ free, the formation sample with scCO₂, and the two or more brine signals.

13. The method of claim 12, further forming a scCO₂ wettability index from the brine wettability index.

14. The method of claim 1, wherein one of the different CO₂ containing states is a CO₂ free state.

15. The method of claim 1, wherein one of the different CO₂ containing states are at a first time during a CO₂ injection into the formation sample and a second time during a storing of the formations sample this is injected with CO₂.

16. A method comprising:
enriching CO₂ with ¹³C to form a CO₂ fluid;
injecting the CO₂ fluid into a formation sample which may contain a liquid;
conducting ¹³C NMR relaxation time (T₂) measurements for at least two states;
finding a ¹³C NMR T₂ shift between the at least two states from the formation sample with the CO₂ fluid; and
finding a wettability index from the ¹³C NMR T₂ shift between the ¹³C NMR relaxation time (T₂) measurements and for at least two different CO₂ containing states.

17. The method of claim 16, wherein one of the at least two different CO₂ containing states are at a first time during a CO₂ injection into the formation sample and a second time during a storing of the formations sample this is injected with CO₂

18. The method of claim 16, wherein the at least two different CO₂ containing states correspond to different CO₂ concentration is the formation sample.

19. The method of claim 16, further comprising injecting the formation sample with a brine solution.

20. The method of claim 19, further comprising finding the ¹³C NMR T₂ shift from the formation sample with the CO₂ fluid and the brine solution.

21. The method of claim 20, further comprising using the ¹³C NMR T₂ shift from the formation sample with the CO₂ fluid and the brine solution to find the wettability index.

22. The method of claim 16, further comprising injecting the formation sample with a brine solution and the CO₂ fluid, wherein the CO₂ fluid is scCO₂.

23. The method of claim 22, further comprising finding the ¹³C NMR T₂ shift from the formation sample with the CO₂ fluid and the brine solution.

24. The method of claim 23, further comprising using the ¹³C NMR T₂ shift from the formation sample with the CO₂ fluid and the brine solution to find the wettability index.
